(19) United States
(12) Patent Application Publication
(10) Pub. No.: US 2006/0261418 A1
(43) Pub. Date: Nov. 23, 2006

(54) MEMORY CELL WITH DOUBLE BB IMPLANT

(75) Inventors: Boaz Eitan, Ra'anana (IL); Rustom Irani, Santa Clara, CA (US)

Correspondence Address: TIAJOLOFF & KELLY, CHRYSLER BUILDING, 37TH FL, 405 LEXINGTON AVE, NEW YORK, NY, 10174, US

(73) Assignee: Saifun Semiconductors Ltd., Netanya (IL)

(21) Appl. No.: 11/461,989

(22) Filed: Aug. 2, 2006

Related U.S. Application Data
(63) Continuation of application No. 11/247,733, filed on Oct. 11, 2005.
(60) Provisional application No. 60/773,673, filed on Feb. 16, 2006.
(60) Provisional application No. 60/618,165, filed on Oct. 14, 2004.

(51) Int. Cl. H01L 29/76

(52) U.S. Cl. 257/390

(57) ABSTRACT

A buried bitline (BB) may be formed in at least two separate implantation steps, in addition to a pocket implant step. The pocket implant has a first width (W1) and a first depth (D1); the first BB implant has a second width (W2) defined by first sidewall spacers and a second depth (D2); the third BB implant has a third width (W3) defined by second sidewall spacers and a third depth (D3); the second width (W2) is less than the first width (W1), and the third width (W3) is less than or equal to the second width (W2); and the second depth (D2) is greater than the first depth (D1), and the third depth (D3) is greater than the second depth (D2). The first BB implant may provide for pocket implant (PI) to bitline (BL) edge optimization; and the second BB implant may provide for controlling BL resistance.

### CROSS-REFERENCE TO RELATED APPLICATIONS

This is a non-provisional filing of U.S. Provisional Application No. 60/773,673, filed 16 Feb. 2006 by Boaz Eitan.

This is a continuation-in-part of U.S. patent application Ser. No. 11/247,733 filed 10 Oct. 2005, which claims priority from U.S. Provisional Application No. 60/618,165 filed 14 Oct. 2004.

### TECHNICAL FIELD

This disclosure relates to nitride read only memory (NROM) and other ONO (oxide nitride oxide) or other microelectronic cells or structures and, more particularly, to cells or structures having buried bitlines (BBs) or other embedded structures.

### BACKGROUND

The present disclosure relates to nitride read only memory (NROM) or other ONO (oxide nitride oxide) cells or other microelectronic structures with buried lines generally and to a method of fabrication thereof and resulting structure(s) in particular.

Dual bit memory cells are known in the art. One such memory cell is the NROM (nitride read only memory) cell 10, shown in FIG. 1A to which reference is now made, which stores two bits 12 and 14 in a nitride based layer 16, such as an oxide-nitride-oxide (ONO) stack, sandwiched between a polysilicon word line 18 and a channel 20. Channel 20 is defined by buried bit line diffusions 22 on each side which are isolated from word line 18 as by a thermally grown oxide layer 26, grown after bit lines 22 are implanted. During oxide growth, bit lines 22 may diffuse sideways, expanding from the implantation area.

NROM cells are described in many patents, for example in U.S. Pat. No. 6,649,972. As shown in FIG. 1B, to which reference is now briefly made, NROM technology may employ a virtual-ground array architecture with a dense crisscrossing of word lines 18 and bit lines 22. Word lines 18 and bit lines 22 optimally can allow a 4F2 size cell, where F designates the design rule (that is, minimum size of an element) of the technology in which the array was constructed. For example, the design rule for a 65 nm technology is F=65 nm. However, most NROM technologies which use the advanced processes of less than 170 nm employ a larger cell, of 4.6-6F2, due to the side diffusion of the bit lines.

A common problem is the integrity of bit line oxides 26. As can be seen in FIG. 1A, they are thick in a middle 25 but shrink to an “oxide beak” 27 at the sides. In general, middles 25 are of good quality but beaks 27 are of poor quality, and thus are susceptible to breakdown. Moreover, the thickness of middles 25 is sensitive to the concentration of n+ doping at the surface of bit line 22 and is thus, difficult to control. In older generation technologies, the solution to this was high temperature oxidation. However, this causes substantial thermal drive, which increases the side diffusion of bit lines 22. Another common problem is that the NROM manufacturing process is significantly different than the periphery CMOS manufacturing process but, to create a wafer with both CMOS and NROM elements, both processes are integrated together. This affects the characterization of the CMOS transistors.

The following patents and patent applications note their attempt to solve these issues and to improve scaling. US 2004/0157393 to Hwang describes a manufacturing process for a non-volatile memory cell of the SONOS type (a type of ONO) which attempts to reduce or minimize the undesirable effects of small dimension components. U.S. Pat. No. 6,686,242 B2 to Willer et al. allegedly describes an NROM cell which arguably can be implemented within a 4F² area.

The above scaling by minimizing the BL side diffusion has two problems associated with it. The first is the high BL resistance and the second is the close relations between the NROM cell performance and the BL dose, energy and side diffusion. Any attempt to improve the BL resistance may end with a lengthy development cycle to re-optimize the cell. This disclosure addresses the above problems. A more complete description of NROM and similar ONO cells and devices, as well as processes for their development may be found at “Non Volatile Memory Technology”, 2005 published by Saifun Semiconductor and materials presented at and through http://siliconnexus.com, both incorporated by reference herein in their entirety.

Glossary

Unless otherwise noted, or as may be evident from the context of their usage, any terms, abbreviations, acronyms or scientific symbols and notations used herein are to be given their ordinary meaning in the technical discipline to which the disclosure most nearly pertains. The following terms, abbreviations and acronyms may be used throughout the descriptions presented herein and should generally be given the following meaning unless contradicted or elaborated upon by other descriptions set forth herein. Some of the terms set forth below may be registered trademarks (®).
bit The word “bit” is a shortening of the words “binary digit.” A bit refers to a digit in the binary numeral system (base 2). A given bit is either a binary “1” or “0”. For example, the number 1001011 is 7 bits long. The unit is sometimes abbreviated to “b”. Terms for large quantities of bits can be formed using the standard range of prefixes, such as kilobit (Kbit), megabit (Mbit) and gigabit (Gbit). A typical unit of 8 bits is called a Byte, and the basic unit for 128 Bytes to 16 K Bytes is commonly referred to as a “page”.
bit line or bitline (BL). a conductor connected to the drain (or source) of a memory cell transistor.
CMOS short for complementary metal oxide semiconductor. CMOS consists of n-channel and p-channel MOS transistors. Due to very low power consumption and dissipation as well minimization of the current in “off” state CMOS is a very effective device configuration for implementation of digital functions. CMOS is a key device in state-of-the-art silicon microelectronics.
   NMOS: n-channel MOS.
   PMOS: p-channel MOS.
Dopant element introduced into semiconductor to establish either p-type (acceptors) or n-type (donors) conductivity; common dopants in silicon: p-type, boron, B; n-type phosphorous, P; arsenic, As; antimony, Sb.
EEPROM short for electrically erasable, programmable read only memory. EEPROMs have the advantage of being able to selectively erase any part of the chip without the need to erase the entire chip and without the need to remove the chip from the circuit. The minimum erase unit is 1 Byte and more typically a full Page. While an erase and rewrite of a location appears nearly instantaneous to the user, the write process is usually slightly slower than the read process; the chip can usually be read at full system speeds.
EPROM short for erasable, programmable read only memory. EPROM is a memory cell in which information (data) can be erased typically by UV light and replaced with new information (data).
Flash Flash memory is a form of non-volatile memory (EEPROM) that can be electrically erased and reprogrammed. Flash memory architecture allows multiple memory locations to be erased or written in one programming operation.
MOS short for metal oxide semiconductor.
nitride commonly used to refer to silicon nitride (chemical formula Si₃N₄). A dielectric material commonly used in integrated circuit manufacturing. Forms an excellent mask (barrier) against oxidation of silicon (Si).
n-type semiconductor in which concentration of electrons is higher than the concentration of “holes”. See p-type. Examples of n-type silicon include silicon doped (enhanced) with phosphorous (P), arsenic (As), antimony (Sb), and the like
NROM short for nitride read only memory.
NVM short for non-volatile memory. NVM is computer memory that can retain the stored information even when not powered. Examples of non-volatile memory include read-only memory, EEPROM, EPROM, Flash memory, most types of magnetic computer storage devices (such as hard disks, floppy disk drives, and magnetic tape), optical disc drives, and early computer storage methods such as paper tape and punch cards. Non-volatile memory is typically used for the task of secondary storage, or long-term persistent storage. The most widely used form of primary storage today is a volatile form of random access memory (RAM), meaning that when the computer is shut down, anything contained in RAM is lost. Unfortunately most forms of non-volatile memory have limitations which make it unsuitable for use as primary storage. Typically non-volatile memory either costs more or performs worse than volatile random access memory.
ONO short for oxide-nitride-oxide. ONO is used as a charge storage insulator consisting of a sandwich of insulating oxide, and charge-trapping nitride.
oxide commonly used to refer to silicon dioxide (SiO₂). Also known as silica. SiO₂ is the most common insulator in semiconductor device technology, particularly in silicon MOS/CMOS where it is used as a gate dielectric (gate oxide); high quality films may be obtained by thermal oxidation of silicon (Si). Thermal SiO2 may form a smooth, low-defect interface with Si, and can be also readily deposited by CVD.
Poly short for polycrystalline silicon (Si). Heavily doped poly Si is commonly used as a gate contact in MOS devices;
p-type semiconductor in which concentration of “holes” is higher than the concentration of electrons. See n-type. Examples of p-type silicon include silicon doped (enhanced) with boron (B), Indium (In) and the like.
PROM short for programmable read-only memory.
RAM short for random access memory. RAM refers to data storage formats and equipment that allow the stored data to be accessed in any order—that is, at random, not just in sequence. In contrast, other types of memory devices (such as magnetic tapes, disks, and drums) can access data on the storage medium only in a predetermined order due to constraints in their mechanical design.
ROM short for read-only memory.
Si Silicon, a semiconductor.
SONOS Si-Oxide-Nitride-Oxide-Si, another way to describe ONO with the Silicon underneath and the Poly gate on top.
Units of Length Various units of length may be used herein, as follows:
   meter (m) A meter is a unit of length, slightly longer than a yard. 1 meter=˜39 inches. 1 kilometer (km)=1000 meters=˜0.6 miles. 1,000,000 microns (μm)=1 meter (m). 1,000 millimeters (mm)=1 meter. 100 centimeters (cm)=1 meter.
   micron (μm) one millionth of a meter (0.000001 meter); also referred to as a micrometer.
   mil 1/1000 or 0.001 of an inch; 1 mil=25.4 microns.
   nanometer (nm) one billionth of a meter (0.000000001 meter).
   Angstrom (Å) one tenth of a billionth of a meter. 10 Å=1 nm.
word line (WL). a conductor normally connected to the gate of a memory cell transistor.

In addition to the above, some abbreviations that may be used herein, or in the provisional application from which this non-provisional application claims priority, include:
BB short for buried bitline.
DNW short for deep N-well.
DPP short for dual poly process.
F short for feature size, which is the minimum size of an element.
HM short for hard mask.
HV OX or HV_OX. short for high voltage oxide.
IMP short for implant.
Mv OX short for medium voltage oxide.
OL short for overlap.
PHOTO short for photoresist or photomask, depending on the context.
PI short for pocket implant.
poly short for polysilicon.
PRECLN short for pre-clean.
PRRM short for photoresist removal
PT short for punchthrough.
PWI short for p-well implant

Further and additional descriptions and explanations of terms, structures, systems and methods may be found in the publication NROM Technology, 2005 published by Saifun Semiconductors and at the website www.siliconnexus.com, both being incorporated herein in their entirety by reference.

### BRIEF DESCRIPTION (SUMMARY)

It is a general object of the disclosure to provide improved techniques for manufacturing memory cells.

According to this disclosure, a method of making a memory cell comprises: forming a buried bitline (BB) in a substrate in at least two separate implantation steps. The method may further comprise performing a pocket implant step. The pocket implant step may be performed before the buried bitline implantation steps. The pocket implant step may be performed through a layer of polysilicon.

According to this disclosure, an NROM memory cell comprises: a semiconductor substrate; an ONO layer disposed on the substrate; a polysilicon layer disposed over the ONO layer; a pocket implant disposed in the substrate at a location under an opening in the polysilicon layer; a first buried bitline (BB) implant disposed in the substrate at the location; and a second buried bitline (BB) implant disposed in the substrate at the location.

According to a feature of this disclosure, the pocket implant has a first width (W1) and a first depth (D1); the first BB implant has a second width (W2) and a second depth (D2); the third BB implant has a third width (W3) and a third depth (D3); the second width (W2) is less than the first width (W1), and the third width (W3) is less than or equal to the second width (W2); and the second depth (D2) is greater than the first depth (D1), and the third depth (D3) is greater than the second depth (D2).

According to a feature of this disclosure, the pocket implant may comprise boron; the first RB implant may comprise arsenic; and the second BB implant may comprise arsenic.

According to a feature of this disclosure, the first BB implant provides for pocket implant (PI) to bitline (BL) edge optimization; and the second BB implant provides for controlling and optimizing the BL resistance.

A buried bitline (BB) formed having one or more dopant concentration area(s) having a feature size less than the minimum feature size provided for (such as contemplated or permitted) under the process design rules for fabricating microelectronic devices, such dopant concentration having areas of higher (or lower) concentration in an otherwise doped region.

### BRIEF DESCRIPTION OF THE DRAWINGS

Reference will be made in detail to embodiments of the disclosure, examples of which may be illustrated in the accompanying drawing figures. The figures are intended to be illustrative, not limiting. Although the disclosure is generally described in the context of these embodiments, it should be understood that it is not intended to limit the disclosure to these particular embodiments.

Certain elements in selected ones of the figures may be illustrated not-to-scale, for illustrative clarity. The cross-sectional views, if any, presented herein may be in the form of “slices”, or “near-sighted” cross-sectional views, omitting certain background lines which would otherwise be visible in a true cross-sectional view, for illustrative clarity. A group of related figures, such as FIGS. 6A-6E, may be referred (shorthand) to as “FIG. 6”.

FIG. 1A is a schematic illustration of an NROM memory cell.

FIG. 1B is a schematic illustration of a layout of the cell of FIG. 1A.

FIGS. 2A and 2B together are a flow chart illustration of a manufacturing method for a novel memory cell.

FIGS. 3A, 3B, 3C, 3D and 3E are schematic illustrations of various stages in the method of FIGS. 2, with FIG. 3E showing the novel memory cell.

FIGS. 4A and 4B are layout illustrations for an array of the cells, useful in understanding the method of FIG. 2.

FIG. 5 is a flow chart illustrating an embodiment of process steps in manufacturing an NROM memory cell, according to this disclosure.

FIGS. 6A-6E are stylized cross-sectional views of a product being formed by the process of FIG. 5, according to this disclosure.

FIG. 7 is a flow chart illustrating another embodiment of process steps in manufacturing an NROM memory cell, according to this disclosure.

FIGS. 8A-8E are stylized cross-sectional views of a product being formed by the process of FIG. 7, according to this disclosure.

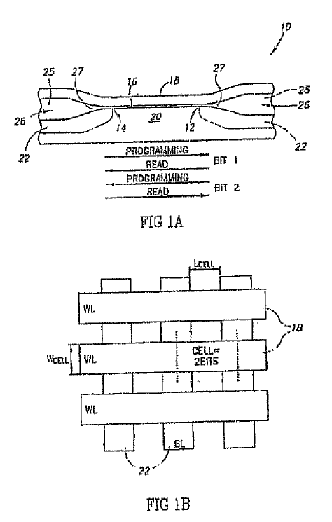

### DETAILED DESCRIPTION

In the following detailed description, numerous specific details are set forth in order to provide a thorough understanding of the disclosure. However, it will be understood by those skilled in the art that the teachings of the present disclosure may be practiced without these specific details. In other instances, well-known methods, procedures, components and circuits have not been described in detail so as not to obscure the teachings of the present disclosure.

Materials (such as silicon dioxide) may be referred to by their formal and/or common names, as well as by their chemical formula. Regarding chemical formulas, numbers may be presented in normal font rather than as subscripts. For example, silicon dioxide may be referred simply as “oxide”, chemical formula SiO2.

In the description that follows, exemplary dimensions may be presented for an illustrative embodiment of the teachings of the disclosure. The dimensions should not be interpreted as limiting. They are included to provide a sense of proportion. Generally speaking, it is the relationship between various elements, where they are located, their contrasting compositions, and sometimes their relative sizes that is of significance.

In the following detailed description, numerous specific details are set forth in order to provide a thorough understanding of the disclosure. However, it will be understood by those skilled in the art that the teachings of the present disclosure may be practiced without these specific details. In other instances, well-known methods, procedures, components and circuits have not been described in detail so as not to obscure the teachings of the present disclosure.

Advanced NROM Structure and Method of Fabrication

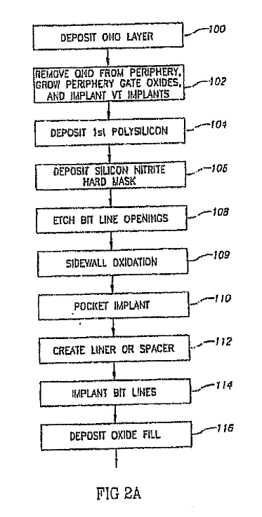

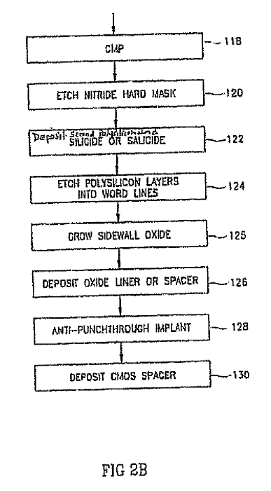

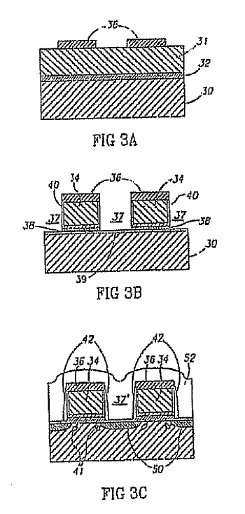

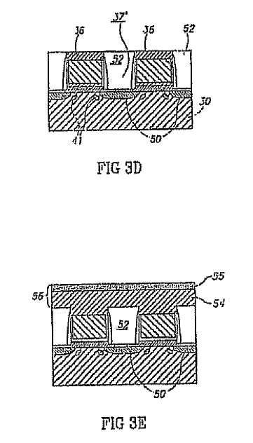

Reference is now made to FIGS. 2A and 2B, which, together, illustrate a process for manufacturing nitride read only memory (NROM) arrays. Reference is also made to FIGS. 3A, 3B, 3C, 3D and 3E which show the results of various steps of FIG. 2 and to FIGS. 4A and 4B which show the layout of various steps of FIG. 2. Note that some figures show hatching as “metal” even though silicon is not actually a metallic element, as “silicon metal” is a common term for pure silicon (see, for example, www.mii.org/minerals/photosil/html and http://minerals.usgs.gov/minerals/pubs/commodity/silicon/760398.pdf, incorporated herein by reference in their entireties).

After preparation of a substrate 30 (FIG. 3A), an ONO layer 32 may be laid down (step 100) over the entire wafer, where, in an exemplary embodiment, the bottom oxide layer may be from 3 to 6 nm; the nitride layer may be from 3 to 8 nm, and the top oxide layer may be from 5 to 15 nm, As an example to a typical ONO layer for 90 mm technology, bottom oxide of 4 nm, nitride of 4 nm and top oxide of 10 nm.

A mask may be laid down and ONO layer 32 may be removed (step 102) from the area of the chip designated for CMOS operation, after which the gate oxides of the periphery may be grown and a threshold voltage doping may be implanted for the CMOS periphery. It will be appreciated that the operations of step 102 may be high thermal budget operations. Moreover, as will be seen hereinbelow, they are effectively the last high thermal budget operations in the present process.

In step 104, a first polysilicon layer 31 may be laid down over the entire chip. A nitride hard mask 36 may then be deposited (step 106) in a column pattern covering the areas of the memory array not destined to be bit lines. FIG. 3A shows the results of step 106. Two columns of nitride hard mask 36 are shown on top of polysilicon layer 31, which overlays ONO layer 32.

An etch may be performed (step 108) to generate bit line openings 37 by removing the areas of polysilicon layer between columns of nitride hard mask layer 36. The etch may be performed in multiple ways.

In one embodiment, it is a polysilicon etch, set to over-etch, for example by 20-50%. The over-etching may then etch away the oxide and nitride layers. For example, if the polysilicon is 70 nm thick and the over-etch is 20%, with a 4/1 poly to oxide etch rate difference, then the over-etch is approximately 3-4 nm, which will reduce a top oxide layer (of 10 nm) to less than 6 nm. If the over-etch is 50%, then it may consume the entire top oxide layer and even consume part of the nitride layer. The over-etch may be set to remove all but the bottom oxide layer.

In another embodiment, the etch may be performed in two steps, a first polysilicon etch to remove all but the bottom oxide layer and a second oxide etch to remove the bottom oxide. The latter may be a very short etch, to remove, for example 2-5 nm of the bottom oxide. Although the etch may also etch silicon substrate 30, it typically may etch only a slight amount (about 0.2-0.5 nm) and thus, may have a minimal affect on the silicon quality. This embodiment may provide a more uniform oxide thickness across the wafer. The latter may improve control of future trajectories of implants into the silicon (steps 110 and 114) and hence, better control of the overlap of the threshold and pocket implants to the bit line implant.

FIG. 3B shows the results of the etch process. Two columns 34 of first polysilicon and nitride hard mask 36 are shown on top of columns 38 of ONO layer 32. The bottom oxide, labeled 39, is shown in bit line openings 37.

Optionally, the array may now be oxidized (step 109), to create a sidewall oxide 40 to cover the now exposed polysilicon 34. An exemplary thickness may be between 1 to 10 nm, for example 5 nm. The oxidation may oxidize other parts of the array, such as the bottom oxide 39 (if present) or the exposed silicon of substrate 30. For the former, bottom oxide 39 may become thicker, such as from 1-5 nm, for example 2 nm thicker. For the latter, the oxidation may react with the exposed silicon, annealing any damage, such as due to the etching of silicon substrate 30. The latter embodiment may provide a better controlled bottom oxide 39 for implanting the bit lines, as described hereinbelow.

A pocket implant 41 (FIG. 3C), such as of Boron (may be using Boron Flourine BF₂), may now be implanted (step 110) next to or under polysilicon columns 34. An exemplary pocket implant may be of 0.5-6×10¹³/cm² (dose of the dopant per unit area) at an angle of for example 0-25° and energy of 10-20 Kev, where the angle may be limited by the width of bit line opening 37 and the height of polysilicon columns 34 covered by nitride hard mask 36. Part of pocket implant 41 may scatter and diffuse under polysilicon columns 34. In an alternative embodiment, the pocket implant may be of Boron or Indium or compounds or alloys containing p type dopants.

In step 112, spacers 42 may be generated on the sides of polysilicon columns 34. For example, spacers 42 may be generated by deposition of an oxide liner, such as of 12 nm, and an anisotropic etch, to create the spacer shape. Alternatively, the liner may be left as it is without forming a spacer

Spacers 42 may decrease the width of bit line openings, labeled 37′ in FIG. 3C, for example, in order to increase the effective length of the channels between bit lines.

Once spacers 42 have been formed, bit lines 50 may be implanted (step 114), followed by a rapid thermal anneal (RTA). In one exemplary embodiment, the bit line implant is of Arsenic of 1.5-3×10¹⁵/cm² at 10-20 Kev and with an angle of 0 or 7% to the bit line.

In step 116, an oxide filler 52 may be deposited on the chip. As can be seen in FIG. 3C, oxide filler 52 may fill reduced bit line openings 37, and may cover other parts of the chip. In step 118, a CMP (chemical mechanical planarization) process may be performed to remove excess oxide filler 52 and to planarize the topology. The result of step 118 is shown in FIG. 3D. As can be seen, the planarization may be designed to remove oxide until it reaches nitride hard mask 36.

In step 120, nitride hard mask 36 may be removed, typically via a nitride wet etch, leaving exposed polysilicon surface above polysilicon elements 34. A second polysilicon layer 54 and a silicide layer 55 may then be deposited (step 122) on the entire wafer. Second polysilicon layer 54 may come into electrical contact with polysilicon elements 34 where the latter are exposed. Layers 54 and 55 may then be etched (step 124) into word lines 56 (FIG. 3E), which may be in rows perpendicular to the bit line columns. To etch the word lines, another nitride hard mask may first be deposited over the silicide layer, followed by an etch of the nitride hard mask, silicide layer 55, second polysilicon layer 54 and first polysilicon columns 34 into word lines 56. It will be appreciated that the first polysilicon is now etched into small islands in electrical contact with and self-aligned to the silicided second polysilicon word lines 56. Furthermore, word lines 56 may extend above and perpendicular to buried diffusion bit lines 50, which may be insulated from them by oxide filler 52.

In another embodiment, the step of depositing silicide layer 55 may be replaced with a salicide (self aligned silicidation) process after word line patterning and CMOS spacer etch.

The layout of polysilicon elements 34 and second polysilicon layer 54 may be seen more clearly in FIG. 4A. As can be seen, polysilicon elements 34 may be laid out in columns, with spacers 42 to their sides, and word lines 56 may be laid out in rows. Bit lines 50 may be implanted between spacers 42 and covered by oxide filler 52. As can be seen, when word lines 56 may be etched, portions 34′ of polysilicon elements 34 between word lines 56 may also be etched, leaving polysilicon elements 34 as islands under word lines 56.

Together, polysilicon elements 34 and word lines 56 may form the gates of each NROM cell. In addition, the polysilicon layers may form the gates, and some interconnections, in the CMOS periphery.

A sidewall oxide 58 (FIG. 4B) may optionally be generated (step 125) to cover the word line surfaces that may be exposed as a result of etch step 124. An oxide liner or partial spacer, of about 10-20 nm, may then be deposited (step 126), along and between word lines 56.

In step 128, an anti-punchthrough implant 59 may be generated between bit lines 50, where portions 34′ of first polysilicon elements 34 were removed. An anti-punchthrough implant may be of Boron (B) of 10-50 Kev at 5-20×10¹²/cm². Alternatively, the anti-punchthrough implant may comprise a multiplicity of implants with different energies and doses in the same location. For example, there might be three consecutive implants of Boron, of 5×10¹² at 15 Kev, 3×10¹² at 25 Kev and 3×10¹² at 35 Kev. Alternatively, the Boron may be replaced by BF2 or Indium, or compounds/alloys containing Boron and/or Indium and/or other p type dopants.

Finally, oxide spacers may be deposited (step 130) for the transistors CMOS periphery. The deposition may cover the entire wafer and may fill or partially fill between word lines 56, providing an insulation between word lines 56.

DPP with Double BB Implant

To improve the optimization of the pocket implant (PI) and the bitline (BL) optimization, it is desired to decouple, as much as possible, the PI-to-BL junction edge and overlap (OL) under the poly, from the BL resistance considerations.

In the process described hereinabove, the BL implant is performed in one step (step 114), after forming (generating) oxide spacers 42 (step 112) on the sides of poly columns 34, and through a reduced-size opening 37′ between adjacent poly columns 34. (Sidewall oxidation 40 omitted from this portion of the discussion.)

According to this embodiment of the disclosure, generally, the buried bitline (BB) implant is performed into two separate steps (in addition to the PI implant)—a first BB implant step that is similar to the process described hereinabove, and a second BB implant which is performed after forming another (a second) spacer in the opening through which the bitline implant is performed. The first BB implant is generally for PI-to-BL edge optimization. The second BB implant generally controls the BL resistance.

The two buried bitline (BB) implantation steps may be performed at the same or with different concentrations, at the same or with different dopants, and at the same or with different energies than one another. Generally, the first bitline implant is designated “BB Imp #1”, and the second bitline implant is designated “BB Imp #2”. For example,

BB Imp #1—1.0-1.5×¹⁵ cm², 10-20 Kev, Arsenic (As)

then a spacer, followed by

BB Imp #2—1-3×10¹⁵ cm², 10-40 Kev, Arsenic (As)

(In the previous example, a single bitline implant was performed with Arsenic at 1.5-3×10¹⁵ cm², 10-20 Kev.)

Thus, a buried bitline (BB) may be formed having a region of higher dopant concentration at one or more portions (such as in the center) of a doped bitline, and such higher concentration region(s) may have a width dimension which is less than the minimum line-width or feature size provided for by the design rules for fabrication of the microelectronics device. Such multiple concentration of dopant in the buried bitline being referred to as a “double buried bitline” (although more than two concentrations or areas of differing concentration are specifically intended and contemplated).

It can be observed, from FIGS. 3C-3E, that the bitline (BL) 50 may extend laterally under (overlaps) the structures 34 of patterned polysilicon 31.

According to this embodiment of the disclosure, the overlap (OL) of BL under poly and the PI-to-BL transition can be optimized for retention, programming and erase. And the BL resistance can be optimized almost independent of the PI to BL transition.

Generally, a process of this embodiment requires one or more extra spacer(s) and one or more extra implant(s), as contrasted with the previously described embodiment.

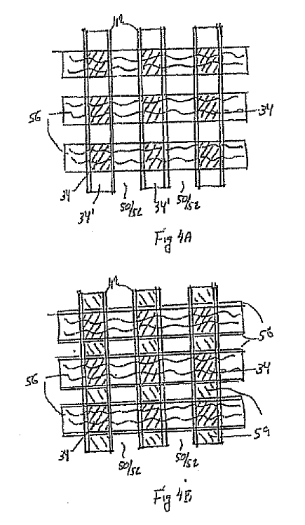

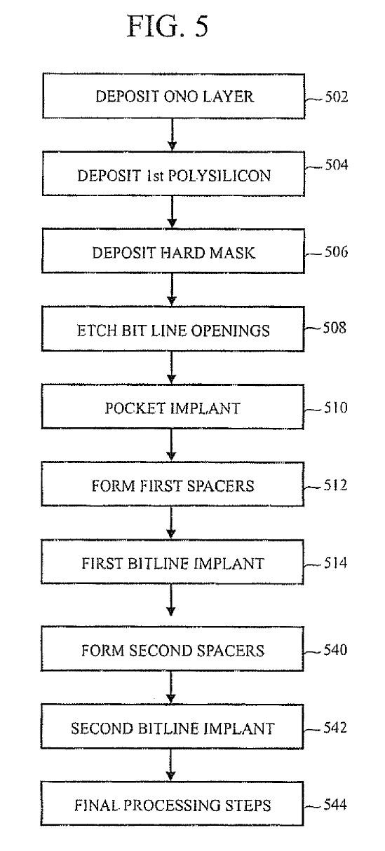

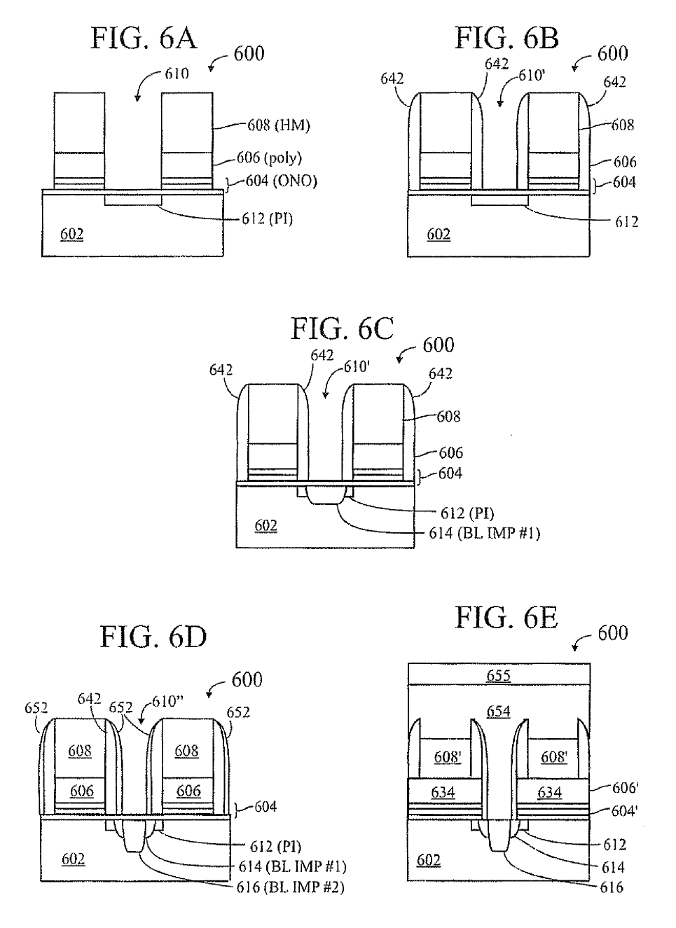

An exemplary process flow is now described. Reference is made to FIG. 5 for the process flow, and to FIGS. 6A-6E showing various, successive stages of the product/structure/apparatus resulting from the process flow.

In a manner which may be similar to that of the previous embodiment, starting with a semiconductor (typically silicon) substrate 602, first, in a step 502, an ONO layer 604 is deposited, using conventional techniques. The ONO layer 604 may have an overall thickness of approximately 10-25 nm (nanometers), such as 18 nM, as follows, although the scope of the disclosure is not limited in this respect:

the bottom oxide layer may be from 3 to 6 mm, for example 4 nm thick;

the middle nitride layer may be from 3 to 8 nm, for example 4 nm thick; and

the top oxide layer may be from 5 to 15 nm, for example 10 nm thick.

In a manner similar to that of the previous embodiment, ONO or parts of the ONO, may be removed from the periphery; growth of periphery gate oxides and implant VT implants may also be performed as discussed hereinabove (step 102), but are omitted from this process flow, for illustrative clarity, although the scope of the disclosure is not limited in this respect.

Next, in a step 504 (compare step 104), a first layer of polysilicon 606 is deposited, using conventional techniques. The first layer of polysilicon (“poly”) may have an exemplary thickness of approximately 30 nm to 100 nm, for example 50 nm, although the scope of the disclosure is not limited in this respect.

Next (as in the previous embodiment), in a step 506 (compare 106), a hard mask 608 is deposited and is patterned. The hard mask 608 may comprise silicon nitride (“nitride”), and may have an exemplary thickness of approximately 50 to 150 nm, for example 50 nm, although the scope of the disclosure is not limited in this respect.

Next (as in the previous embodiment), in a step 508 (compare 108) bit line openings 610 are etched. to have openings 610 at positions where pocket implants and bit line implants will be formed (implanted) in the underlying substrate 602, as discussed hereinbelow. Etching of the hard mask 608 and usually polysilicon 606 is suitably stopped (such as using selective etching) on the bottom oxide layer of the ONO layer 604, using conventional techniques, although the scope of the disclosure is not limited in this respect.

Next (as in the previous embodiment), in a step 510 (compare 110), a pocket implant 612 is implanted through the ONO 604, in an area of the substrate 602 under the opening 610, using conventional techniques, although the scope of the disclosure is not limited in this respect. An exemplary pocket implant 612 may be of 0.5-6×10¹³/cm2 (dose of the dopant per unit area) and energy of 10-20 Kev (as in the previous example), 0-25° tilt, boron (B), although the scope of the disclosure is not limited in this respect. The resulting structure is shown in FIG. 6A.

Next (as in the previous embodiment), in a step 512 (compare 112), first spacers 642 are formed on the inside walls of the opening 610 extending through the hard mask 608 and the poly 606. Supposing that the opening 610 has a dimension F (minimum feature size), the first spacers 642 usually reduce the size of the opening such as to F minus two times the spacer thickness. The first spacers 642 may be of nitride or oxide or poly or other suitable material, and may have an exemplary thickness of approximately 10-20 nm, such as 12 nm. Therefore, the resulting opening 610′ (reduced-size opening 610) measures F−24 nm (F−(2×12 nm)), although the scope of the disclosure is not limited in this respect. Thus, the resulting opening has a dimension (width, in this case), which is less than the minimum feature size (F) provided for (such as contemplated or permitted) under the process design rules. The resulting structure is shown in FIG. 6B.

Generally, the purpose of the spacer 642 is to achieve an opening having a size which is less than F, the minimum feature size which can be achieved using lithographic techniques. So, if the original opening 610 has the minimum achievable feature size of F, and it is desired to do a self-aligned implant using the feature, by depositing material (the spacer) on the inner walls of the opening, an opening 610′ having a feature size of <F (less than F) can be achieved. The resulting structure is shown in FIG. 6B.

By way of example, F 65 nm, the opening 610′ measures 41 nm across (left-to-right as viewed in the Figure). The pocket implant 612 is centered under the opening 610′, and measures 65 nm across, and 15 nm deep (vertical, into the substrate, as viewed in the Figure.) The pocket implant 612 is wider across than the opening 610′.

Next, in a step 514, a first buried bitline implant (BL IMP #1) is performed. The first buried bitline implant is labeled 614 (FIG. 6C), and is centered under the opening 610′. The first buried bitline implant may be of 1.0-1.5E¹⁵ cm², 10-20 Kev, Arsenic (As), through the ONO Bottom Oxide, although the scope of the disclosure is not limited in this respect.

As mentioned above, this first buried bitline implant (BL IMP #1) may or may not be through the ONO bottom oxide or through the ONO nitride and bottom oxide. If the bottom oxide was removed during forming the openings in the poly 606, an oxidation step may be performed to protect the bare silicon, as discussed above, although the scope of the disclosure is not limited in this respect. The resulting structure is shown in FIG. 6C.

By way of example, the first bitline implant 614 measures 40 nm across, and 25 nm deep (vertical, into the substrate, as viewed in FIG. 6C.)

Next, in a step 540, second spacers 652 are formed within the opening 610′, generally on the exposed surfaces of the first spacers 642, using conventional processes. The second spacers 642 may be of nitride or oxide, or other materials, and may have an exemplary thickness of approximately 5-12 nm. Therefore, the resulting opening 610″ between word lines 634 measures F minus 24 nm (twice the thickness of the first spacers), minus 10-24 nm (twice the thickness of the second spacers 652), although the scope of the disclosure is not limited in this respect.

Next, in a step 542, a second buried bitline implant (BL IMP #2) is performed. The second buried bitline implant is labeled 616 (FIG. 6D), and is centered under the opening 610″. The second buried bitline implant may be of 1-3E¹⁵ cm², 10-40 Kev, Arsenic (As), through the ONO Bottom Oxide, although the scope of the disclosure is not limited in this respect.

If the bottom oxide layer of the ONO 604 is still in place (as shown), the second bitline implant is performed through the bottom layer of the ONO. The resulting structure is shown in FIG. 6D.

By way of example, the second bitline implant 616 measures 30 nm across, and 50 nm deep (vertical, into the substrate, as viewed in the FIG. 6D.)

By using the techniques of this disclosure, a double buried bitline (BB) may be formed within the substrate 602, aligned under an opening 610 (610′, 610″) between poly structures 634 and having the following relative dimensions and geometry:

a pocket implant 612 having a first width (W1) and a first depth (D1);

a first BB implant 614 which is vertically aligned with the pocket implant and having a second width (W2) which is less than the first width (W2<W1), such as less than 90% of the width of the pocket implant, including less than 80%, less than 70% less than 60% and approximately 50% less.

the first BB implant 614 has a second depth (D2) which may be greater than the first depth (D1), such as at least 10% greater, including at least 25% greater, at least 50% greater, at least 75% greater and approximately 100% greater.

a second BB implant 616 which is vertically aligned with the first BB implant and having a third width (W3) which may be less than the second width (W3<W2), such as less than 90% of the width of the first BB implant, including less than 80%, less than 70% less than 60% and approximately 50% less.

the second BB implant 616 has a third depth (D3) which may be greater than the second depth (D2), such as at least 10% greater, including at least 25% greater, at least 50% greater, at least 75% greater and approximately 100% greater.

Finally, an oxide fill 652 is deposited and may be chem-mech polished, or otherwise planarized or reduced in cross-sectional height, followed by removal of the Nitride Hard Mask depositing a second polysilicon layer 654 and a silicide layer 655, using conventional techniques. Generally, all of the final processing steps 116-130, described hereinabove (designated in FIG. 5 as step 544), can be performed on the nearly-final product shown in FIG. 6D to arrive at the “final” structure shown in FIG. 6E, although the scope of the disclosure is not limited in this respect.

This embodiment is generally a simple addition to the previously-described process, and the optimization that can be achieved generally justifies the extra process steps (two sidewall spacers rather than one, two bitline implants rather than one).

Another Embodiment (Implant Through Poly)

The two embodiments described above (FIG. 3 and FIG. 6) are similar to one another in that the pocket implant (PD and the bitline (BL) implant(s) are made through openings (37, 610) in the poly (31, 606). (And, in both embodiments, the lower oxide layer of the ONO layer (32, 604) was generally left in place.) A difference between the two embodiments was that rather than performing just one BL implant (FIG. 3), two BL implants (FIG. 6) are performed, with a spacer between the two BL implants.

In this embodiment, generally, the pocket implant is made through the poly, before being opened. Then, two bitline (BL) implants are performed, in a manner similar to that of the previous (FIG. 6) embodiment.

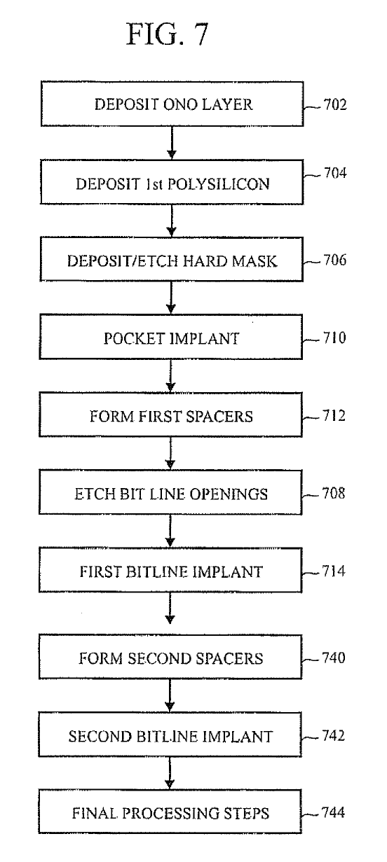

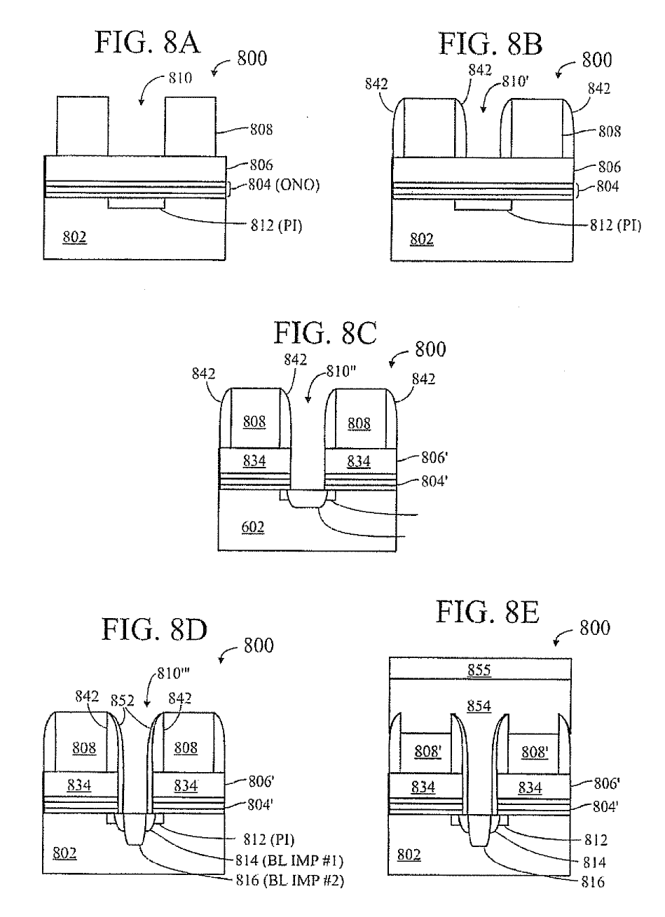

FIGS. 7 and 8 are generally comparable to FIGS. 5 and 6 (as well as to FIGS. 2 and 3) in that the former (FIGS. 2,5,7) shows the process flow and the latter (FIGS. 3,6,8) illustrates a product being formed by the process flow, respectively.

To improve the optimization of the pocket implant (PI) and the bitline (BL) optimization, it is desired to decouple, as much as possible, the PI-to-BL junction edge and overlap (OL) under the poly, from the BL resistance considerations.

In the process described hereinabove (FIGS. 2 and 3), the BL implant is performed in one step (step 114), after forming (generating) oxide spacers 42 (step 112) on the sides of poly columns 34, and through a reduced-size opening 37′ between adjacent poly columns 34. (Sidewall oxidation 40 omitted from this portion of the discussion.)

According to this embodiment of the disclosure, generally, the buried bitline (BB) implant is performed into two separate steps (in addition to the PI implant)—a first BB implant step that is similar to the process described hereinabove, and a second BB implant which is performed after forming another (a second) spacer in the opening through which the bitline implant is performed. The first BB implant is generally for PI-to-BL edge optimization. The second BB implant generally controls the BL resistance.

The two buried bitline (BB) implantation steps may be performed at the same or with different concentrations, at the same or with different dopants, and at the same or with different energies than one another. Generally, the first bitline implant is designated “BB Imp #1”, and the second bitline implant is designated “BB Imp #2”. For example,

BB Imp #1—1.0-1.5×10¹⁵ cm, 10-20 Kev, Arsenic (As)

then a spacer, followed by

BB Imp #2—1-3×10¹⁵ cm², 10-40 Kev, Arsenic (As)

(In the previous example, a single bitline implant was performed with Arsenic at 1.5-3×10¹⁵ cm², 10-20 Kev.)

Thus, a buried bitline (BB) may be formed having a region of higher dopant concentration at one or more portions (such as in the center) of a doped bitline, and such higher concentration region(s) may have a width dimension which is less than the minimum line-width or feature size provided for by the design rules for fabrication of the microelectronics device. Such multiple concentration of dopant in the buried bitline being referred to as a “double buried bitline” (although more than two concentrations or areas of differing concentration are specifically intended and contemplated).

It can be observed, from FIGS. 3C-3E, that the bitline (BL) 50 may extend laterally under (overlaps) the structures 34 of patterned polysilicon 31.

According to this embodiment of the disclosure, the overlap (OL) of BL under poly and the PI-to-BL transition can be optimized for retention, programming and erase. And the BL resistance can be optimized almost independent of the PI to BL transition.

Generally, a process of this embodiment requires one or more extra spacer(s) and one or more extra implant(s), as contrasted with the previously described embodiment.

An exemplary process flow is now described. Reference is made to FIG. 7 for the process flow, and to FIGS. 8A-8E showing various, successive stages of the product/structure/apparatus resulting from the process flow.

In a manner which may be similar to that of the previous embodiments, starting with a semiconductor (typically silicon) substrate 802, first, in a step 702, an ONO layer 804 is deposited, using conventional techniques. The ONO layer 804 may have an overall thickness of approximately 10-25 nm, such as 18 nm, as follows, although the scope of the disclosure is not limited in this respect:

the bottom oxide layer may be from 3 to 6 nm, for example 4 nm thick;

the middle nitride layer may be from 3 to 8 nm, for example 4 nm thick; and

the top oxide layer may be from 5 to 15 nm, for example 10 nm thick.

In a manner similar to that of the previous embodiment, ONO or parts of the ONO, may be removed from the periphery; growth of periphery gate oxides and implant VT implants may also be performed as discussed hereinabove, but are omitted from this process flow, for illustrative clarity, although the scope of the disclosure is not limited in this respect.

Next, in a step 704, a first layer of polysilicon 806 is deposited, using conventional techniques. The first layer of polysilicon (“poly”) may have an exemplary thickness of approximately 30 nm to 100 nm, for example 50 nm, although the scope of the disclosure is not limited in this respect.

Next, in a step 706, a hard mask 808 is deposited and is patterned (etched) to have openings 810 at positions where pocket implants (P1) and bit line (BL) implants will be formed (implanted) in the underlying substrate 802, as discussed hereinbelow. Etching of the hard mask 808 is suitably stopped (such as using selective etching) on the underlying poly 806, using conventional techniques. The hard mask 808 may comprise silicon nitride (“nitride”), and may have an exemplary thickness of approximately 50 to 150 nm, for example 50 nm, although the scope of the disclosure is not limited in this respect.

Here is where the present embodiment deviates from the previously-described embodiments—namely, pocket implant is performed through the poly, as described hereinbelow.

Next, in a step 710, a pocket implant 812 is implanted, through the poly 806 and through the ONO 804, in an area of the substrate 802 under the opening 810, using conventional techniques, although the scope of the disclosure is not limited in this respect.

Notice that, in this embodiment, the steps 108 (etch bit line openings) and 109 (sidewall oxidation) of the previous embodiment are not performed before the step of pocket implant (step 710), although the scope of the disclosure is not limited in this respect.

An exemplary pocket implant 812 may be of 0.5-6×10¹³/cm2 (dose of the dopant per unit area) and energy of 10-20 Kev (as in the previous example), no tilt, boron (B), although the scope of the disclosure is not limited in this respect. Generally, the energy depends on the poly thickness. The pocket implant 812 may be BF2 or Indium (less likely in this case due to the required deep trajectory that is required), as well as boron (B). The resulting structure is shown in FIG. 8A.

Next, in a step 712, first spacers 842 are formed on the inside walls of the opening 810 in the hard mask 808. Supposing that the opening 810 has a dimension F (minimum feature size), the spacers usually reduce the size of the opening such as to F minus two times the spacer thickness. The first spacers 842 may be of nitride or oxide, and may have an exemplary thickness of approximately 10-20 nm or 12 nm as an example: Therefore, the resulting opening 810′ in the mask 808 measures F−24 nm (F−(2×12 nm)), although the scope of the disclosure is not limited in this respect. Thus, the resulting opening has a dimension (width, in this case), which is less than the minimum feature size provided for (such as contemplated or permitted) under the process design rules. The resulting structure is shown in FIG. 8B.

There is now disclosed one type of a departure from the previously described method. In the previously-described method, the (only) spacer 42 is formed on the opening 37 which expectedly extends through both the nitride mask 36 and the poly 31. In this embodiment, there is no opening in the poly 806 (yet), so the first spacer 842 is formed only on the sidewalls of the opening 810 in the nitride mask, although the scope of the disclosure is not limited in this respect.

Generally, the purpose of the spacer 842 is to achieve an opening having a size which is less than F, the minimum feature size which can be achieved using lithographic techniques. So, if the original opening 810 has the minimum achievable feature size of F, and it is desired to do a self-aligned implant using the feature, by depositing material (the spacer) on the inner walls of the opening, an opening 810′ having a feature size of <F (less than F) can be achieved. The resulting structure is shown in FIG. 8B.

By way of example, F=65 nm, the opening 810′ measures 41 nm across (left-to-right as viewed in the Figure). The pocket implant 812 may be centered under the opening 810, and measures 65 nm across, and 15 nm deep (vertical, into the substrate, as viewed in the Figure.) The pocket implant 812 is wider across than the opening 810.

Next, in a step 708, the poly 806 and the underlying ON layer is etched to create an opening 810″, using conventional techniques, leaving the bottom oxide in place (as described hereinabove). The modified (etched) poly 806 and ONO 804 are designated 806′ and 804′, respectively, in FIG. 8C. The opening 810″ is essentially an extension of the opening 810′, and is at a location where it is desired to subsequently perform a first of at least two buried bitline (BB) implantation steps.

The bottom oxide layer of the ONO layer 804 may be left in place, as discussed hereinabove, although it is shown removed in the Figure (FIG. 8C). The variations of this step (leaving the bottom oxide layer in place, or removing it then oxidizing exposed silicon), discussed hereinabove, are relevant to this process flow, although the scope of the disclosure is not limited in this respect.

Sidewall oxidation of the polysilicon structures 834 may or may not be performed, as discussed hereinabove, but is omitted from this process flow (as well as from the Figure) for illustrative clarity, although the scope of the disclosure is not limited in this respect.

Next, in a step 714, a first buried bitline implant (BL IMP #1) is performed. The first buried bitline implant is labeled 814 (FIG. 8C), and is centered under the opening 810″. The first buried bitline implant may be of 1.0-1.5E¹⁵cm², 10-20 Kev, Arsenic (As), through the ONO Bottom Oxide, although the scope of the disclosure is not limited in this respect.

As mentioned above, this first buried bitline implant (BL IMP #1) may or may not be through the ONO bottom oxide. If the bottom oxide was removed during forming the openings in the poly 806, an oxidation step may be performed to protect the bare silicon, as discussed above, although the scope of the disclosure is not limited in this respect. The resulting structure is shown in FIG. 8C.

By way of example, the first bitline implant 814 measures 40 nm across, and 25 nm deep (vertical, into the substrate, as viewed in FIG. 8C.)

Next, in a step 740, second spacers 852 are formed within the opening 810″, including on the first spacers 842 as well as extending downward into the opening 810″ and on the on the sidewalls of the poly structures 834, using conventional processes. The second spacers 842 may be of nitride or oxide, or other materials, and may have an exemplary thickness of approximately 5-12 nm: Therefore, the resulting opening 810′″ between word lines 834 measures F minus 24 nm (twice the thickness of the first spacers), minus 10-24 nm (twice the thickness of the second spacers 852), although the scope of the disclosure is not limited in this respect.

Next, in a step 742, a second buried bitline implant (BL IMP #2) is performed. The second buried bitline implant is labeled 816 (FIG. 8D), and is centered under the opening 810′″. The second buried bitline implant may be of 1-3E¹⁵cm², 10-40 Kev, Arsenic (As), through the ONO Bottom Oxide, although the scope of the disclosure is not limited in this respect.

If the bottom oxide layer of the ONO 804 is still in place, the second bitline implant is performed through the bottom layer of the ONO. The resulting structure is shown in FIG. 8D.

By way of example, the second bitline implant 816 measures 30 nm across, and 50 nm deep (vertical, into the substrate, as viewed in the FIG. 8D.)

By using the techniques of this disclosure, a double buried bitline (BB) may be formed within the substrate 802, aligned under an opening 814′ between poly structures 834 and having the following relative dimensions and geometry:

a pocket implant 812 having a first width (W1) and a first depth (D1);

a first BB implant 814 which is vertically aligned with the pocket implant and having a second width (W2) which is less than the first width (W2<W1), such as less than 90% of the width of the pocket implant, including less than 80%, less than 70% less than 60% and approximately 50% less.

the first BB implant 814 has a second depth (D2) which may be greater than the first depth (D1), such as at least 10% greater, including at least 25% greater, at least 50% greater, at least 75% greater and approximately 100% greater.

a second BB implant 816 which is vertically aligned with the first BB implant and having a third width (W3) which may be less than the second width (W3<W2), such as less than 90% of the width of the first BB implant, including less than 80%, less than 70% less than 60% and approximately 50% less.

the second BB implant 816 has a third depth (D3) which may be greater than the second depth (D2), such as at least 10% greater, including at least 25% greater, at least 50% greater, at least 75% greater and approximately 100% greater.

Finally, an oxide fill 852 is deposited and may be chem-mech polished, or otherwise planarized or reduced in cross-sectional height, followed by removal of the Nitride Hard Mask and depositing a second polysilicon layer 854 and a silicide layer 855, using conventional techniques. Generally, all of the final processing steps 116-130, described hereinabove (designated in FIG. 7 as step 744), can be performed on the nearly-final product shown in FIG. 8D to arrive at the “final” structure shown in FIG. 5E, although the scope of the disclosure is not limited in this respect.

This embodiment is generally a simple addition to the previously-described process (FIGS. 2, 3), and the optimization that can be achieved generally justifies the extra process steps (two sidewall spacers rather than one, two bitline implants rather than one).

While a number of exemplary aspects and embodiments have been discussed above, those of skill in the art will recognize certain modifications, permutations, additions and sub-combinations thereof. It is therefore intended that the following appended claims and claims hereafter introduced be interpreted to include all such modifications, permutations, additions and sub-combinations.

What is claimed is:

1. Non-volatile memory (NVM) cell comprising:
an ONO layer disposed on a semiconductor substrate;
a polysilicon layer disposed over the ONO layer;
a pocket implant disposed in the substrate at a location under an opening in the polysilicon layer;
a first buried bitline (BB) implant disposed in the substrate at the location;
a spacer in the opening, forming a reduced-size opening; and
a second buried bitline (BB) implant disposed in the substrate at a location under the reduced-size opening.

2. The memory cell of claim 1, wherein:
the pocket implant (612) has a first width (W1) and a first depth (D1);
the first BB implant has a second width (W2) and a second depth (D2);
the third BB implant has a third width (W3) and a third depth (D3);
the second width (W2) is less than the first width (W1), and the third width (W3) is less than or equal to the second width (W2); and
the second depth (D2) is greater than the first depth (D1), and the third depth (D3) is greater than the second depth (D2).

3. The memory cell of claim 1, wherein:
the pocket implant comprises boron;
the first BB implant comprises arsenic; and
the second BB implant comprises arsenic.

4. The memory cell of claim 1, wherein:
the first BB implant provides for pocket implant (PI) to bitline (BL) edge optimization;
the second BB implant provides for controlling BL resistance.

5. Non-volatile memory (NVM) cell comprising:
an ONO layer disposed on a substrate;
a polysilicon layer disposed over the ONO layer;
a hard mask disposed over the polysilicon layer;
a first opening in the hard mask;
first spacers disposed on sidewalls of the first opening in the hard mask, resulting in a second opening;
a third opening extending through the polysilicon as an extension of the second opening; and
second sidewall spacers disposed on the first spacers and on sidewalls of the further opening, resulting in a fourth opening.

6. The memory cell of claim 5, further comprising:
a pocket implant disposed in the substrate at a location under the first opening and defined by the first opening.

7. The memory cell of claim 5, further comprising:
a first BB implant disposed in the substrate at a location under the third opening and defined by the third opening.

8. The memory cell of claim 5, further comprising:
a second BB implant disposed in the substrate at a location under the fourth opening and defined by the fourth opening.

9. The memory cell of claim 5, further comprising:
a pocket implant disposed in the substrate at a location under the first opening and defined by the first opening;
a first BB implant disposed in the substrate at a location under the third opening and defined by the third opening; and
a second BB implant disposed in the substrate at a location under the fourth opening and defined by the fourth opening.

10. The memory cell of claim 5, wherein:
the pocket implant has a first width (W1) and a first depth (D1);
the first BB implant has a second width (W2) and a second depth (D2);
the third BB implant has a third width (W3) and a third depth (D3);
the second width (W2) is less than the first width (W1), and the third width (W3) is less than the second width (W2); and
the second depth (D2) is greater than the first depth (D1), and the third depth (D3) is greater than the second depth (D2).

11. Method of making a memory cell comprising:
performing a first buried bitline (BB) implant through an opening;
after the first BB implant, forming a spacer in the opening, thereby reducing the size of the opening;
after forming the spacer, performing a second bitline (BB) implant through the reduced size opening.

12. The method of claim 11, further comprising:
performing a pocket implant step.

13. The method of claim 12, wherein the pocket implant step is performed before the buried bitline implantation steps.

14. The method of claim 12, wherein the pocket implant step is performed through an opening in a mask.

15. The method of claim 12, wherein the pocket implant step is performed through a layer of polysilicon underlying the mask.

16. The method of claim 1, wherein a first of the at least two separate implantation steps is performed through an opening defined by first sidewall spacers.

17. The method of claim 16, wherein a second of the at least two separate implantation steps is performed through an opening defined by second sidewall spacers overlying the first sidewall spacers.

18. The method of claim 17, wherein:
the first of the at least two separate implantation steps results in a first BB implant having a first width;
the second of the at least two separate implantation steps results in a second BB implant having a second width which is less than or equal to the first width.

19. The method of claim 11, further comprising:
performing a pocket implant step results in a pocket implant having a first width (W1) and a first depth (D1);
wherein:
a first of the at least two separate implantation steps results in a first BB implant having a second width (W2) and a second depth (D2);
a second of the at least two separate implantation steps results in a second BB implant having a third width (W3) and a third depth (D3);
the second width (W2) is less than the first width (W1), and the third width (W3) is less than or equal to the second width (W2); and
the second depth (D2) is greater than the first depth (D1), and the third depth (D3) is greater than the second depth (D2).

20. The method of claim 11, wherein:
a first of the at least two implantation steps is for pocket implant (PI) to bitline (BL) edge optimization; and
a second of the at least two implantation steps is for controlling BL resistance.

21. Non-volatile memory (NVM) cell comprising:
a buried bitline (BB) formed having multiple dopant concentration areas, at least one of which has a feature size less than a minimum feature size provided for under process design rules for fabricating microelectronic devices, at least one of the dopant concentration areas being defined by sidewall spacers formed in an opening after one of the dopants has been implanted and before a subsequent dopant is implanted.

22. The memory cell of claim 21, wherein:
one of the dopant concentration areas has a higher dopant concentration than another of the dopant concentration areas.
